(19) United States
(12) Patent Application Publication
(10) Pub. No.: US 2012/0216852 A1
(43) Pub. Date: Aug. 30, 2012

(54) SOLAR TRACKER DRIVE

(75) Inventors: CHARLES ALMY, Berkeley, CA (US); Nicholas Barton, Richmond, CA (US)

(73) Assignee: SunPower Corporation, San Jose, CA (US)

(21) Appl. No.: 13/402,769

(22) Filed: Feb. 22, 2012

Related U.S. Application Data
(60) Provisional application No. 61/445,181, filed on Feb. 22, 2011.

(51) Int. Cl. H01L 31/042; G05B 11/01

(52) U.S. Cl. 136/246; 318/489

(57) ABSTRACT

A solar energy collection system can include a drive configured to adjust a tilt position of a solar collector assembly so as to tract the sun. The drive can include hardware for providing feedback control of the orientation of the solar collector assembly. A method for calibrating the drive can include moving the drive to a reference position and saving an output value from a sensor configured to detect the orientation of the drive. The reference value output from the sensor can then be used in determining the target output value from the sensor required to achieve a desired orientation.

### CROSS-REFERENCE TO RELATED APPLICATIONS

This application is based on and claims priority to U.S. Provisional Patent Application No. 61/445,181, filed on Feb. 22, 2011, the entire contents of which is hereby expressly incorporated by reference.

### TECHNICAL FIELD

Embodiments of the subject matter described herein relate generally to solar energy systems which include drive systems for sun tracking, solar energy collecting devices.

### BACKGROUND

Some larger solar collector installations include an array of sun tracking, solar power collector assemblies. Such assemblies can be used in conjunction with photovoltaic modules, concentrated photovoltaic modules, as well as concentrated thermal solar collector devices.

Such sun-tracking collectors include hardware for automatically adjusting the position of the collector devices to track the sun as it moves across the sky. This tracking movement can be accomplished in a number of different ways. Some systems use a single axis tracking system in which the collector devices pivot about a single axis. Such single axis type tracking systems often include a drive shaft or “torque tube” which defines a single pivot axis.

Concentrated photovoltaic solar systems can provide significant cost savings over non-concentrated photovoltaic systems. This is because concentrated photovoltaic system only use a fraction of the amount of photovoltaic material to collect about the same amount of sunlight. However, sun-tracking accuracy becomes more important with concentrated systems. For example, it is known that efficiency of a solar collector can drop if the mirrors of a concentrated system are misaligned by as little as 0.1°. Thus, high performance of such systems is more likely to be achieved if the components of the concentrated systems are manufactured to precise tolerances. Additionally, such concentrated photovoltaic systems are more affordable, if the hardware and/or labor required to construct such a system is reduced.

### BRIEF SUMMARY

An aspect of at least one of the inventions disclosed herein includes the realization that certain labor-intensive tasks that have previously been performed on the construction site of a photovoltaic system, can be performed more quickly, accurately, and/or with less cost if certain activities can be performed in a controlled environment, such as a manufacturing facility. For example, one step of constructing a concentrated photovoltaic system is the calibration of the sun-tracking drives. Each of the motors include an inclination sensor (inclinometer) which provides an output for indicating the rotational position of each collector module. However, if an inclinometer is not properly calibrated, the corresponding collector would be rotated to an incorrect position. As noted above, an error as little as one-half or 0.1° can significantly impact efficiency.

One approach to calibrating such drives is to manually rotate a collector to a reference position, such as “stowed” or level position and using an accurate level or other calibrated high-accuracy inclinometer to confirm the accuracy of the output of an attached inclinometer, through the full range of motion of the collector. This procedure would be repeated for every sun-tracking drive in an solar power farm. However, the installation sites for solar facilities can be in remote locations, subject to hot weather, and can be grounds for wildlife, such as snakes. Thus, reducing the labor to be performed in such locations can significant reduce labor costs.

Thus, in accordance with at least one embodiment, a sun-tracking drive which includes an actuator and an inclination sensor, can be pre-calibrated in a controlled environment. For example, such a sun-tracking drive, which includes a dedicated inclinometer, can be placed in a controlled facility, such as a manufacturing facility. An output member of the drive can be rotated to a reference position, the orientation of which can be confirmed with high accuracy instrument. The output of the dedicated inclinometer can be recorded and stored. This reference position output can be considered an offset. For example, if the drive member is rotated to a level position, which can be considered a 0° position, but the output from the inclinometer indicates a 0.5° inclination, then 0.5° can be stored as an indication of the offset of the output from the inclinometer to the actual inclination. This offset value can be used in a future operation of the sun-tracker so that the ultimate position of the solar collector matches the target orientation.

Thus, in accordance with at least one of the embodiments disclosed herein, a method can be provided for using a sun-tracking drive which includes a motor mechanically interfaced with a drive member and having a connector configured to engage a frame of a photovoltaic collector assembly such that the motor can drive the frame through a pivoting motion about a tilt axis for tracking movement of the sun. The method can include attaching an inclinometer to the drive member, rotating the drive member to a reference position, and detecting an output from the inclinometer with the drive member at the reference position. The output from the inclinometer can be stored in a memory device as an offset value indicative of the output from the inclinometer when the drive member is in the reference position.

In accordance with another embodiment, a photovoltaic electricity farm can comprise a plurality of support frames. Each of the support frames support a plurality of photovoltaic modules and a plurality of solar-concentrating mirrors, configured to focus light onto the photovoltaic modules, each of the frames being mounted so as to be pivotable about at least a first tilt axis. A plurality of sun-tracking drives, each connected to at least one of the plurality of support frames, can also be provided. Each of the plurality of tracking drives can include a motor mechanically interfaced with a drive member, the drive member including a connector engaged with one of the plurality of support frames, the motor being configured to pivot the support frame about a tilt axis for tracking movement of the sun. An inclinometer can also be mounted to the drive member. A controller can include a network communication device and a memory device, the controller being connected to the inclinometer so as to receive an output signal from the inclinometer. A reference value can be stored in the memory device that is indicative of an output of the inclinometer when the drive member was positioned in a reference position before being connected to the support frame.

In yet another embodiment, a method can be provided for using a sun-tracking drive. The sun-tracking drive can include a motor mechanically interfaced with a drive member having a connector configured to engage a frame of the concentrated photovoltaic collector assembly such that the motor can drive the frame through a pivoting motion about a tilt axis for tracking movement of the sun. The method can include attaching an inclinometer to the drive member and calibrating the position of the drive member with the output of the inclinometer before attaching the drive member to the support frame in an outdoor, photovoltaic electricity farm.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIG. 1 is a schematic top plan view of a non-concentrated solar collector system including a sun-tracking drive in accordance with an embodiment;

FIG. 2 is a schematic diagram of the system illustrated in FIG. 1 illustrating optional electrical connections of the collector system with various electrical components;

FIG. 3 is a perspective view of the solar collection system of FIG. 1, illustrating a plurality of piles mounted to the ground and supporting a plurality of torque tubes with a sun-tracking drive in accordance with an embodiment;

FIG. 4 is a schematic side elevational view of a concentrated photovoltaic assembly in which the sun-tracking drive can also be used;

FIG. 5 is a perspective view of an embodiment of a bearing that can be used with any of the embodiments illustrated in FIGS. 1-4;

FIG. 6 is a perspective view of a sun-tracker drive of the concentrated photovoltaic assembly of FIG. 4;

FIG. 7 is a schematic diagram of a controller that can be used with the sun-tracker drive of FIG. 6;

FIG. 8 is a flow chart illustrating a method that can be used for calibrating the drive of FIG. 7;

FIG. 9 is a flow chart illustrating an optional method for using the sun-tracker drive of FIGS. 1-7;

FIG. 10 is an enlarged perspective view of the sun-tracker drive and mounting hardware illustrated in FIG. 6; and

FIG. 11 is a top plan view of the sun-tracker drive of FIG. 10.

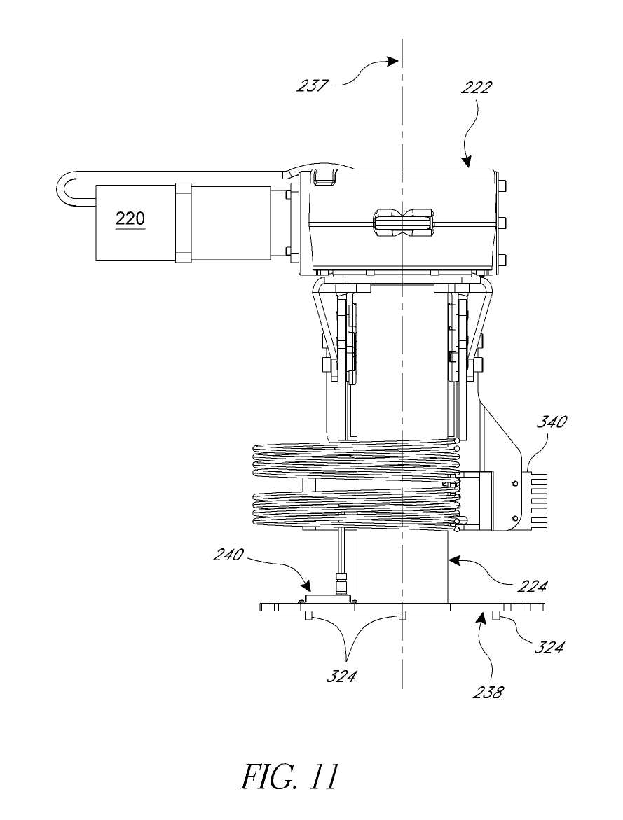

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the proceeding technical field, background, brief summary, or the following detailed description.

Certain terminology may be used in the following description for the purpose of reference only, and thus are not intended to be limiting. For example, terms such as “upper”, “lower”, “above”, and “below” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second”, and other such numerical terms referring to structures do not imply a sequence or order unless clearly indicated by the context.

The inventions disclosed herein are described in the context of non-concentrated and concentrated photovoltaic arrays and modules. However, these inventions can be used in other contexts as well, such as concentrated thermal solar systems, etc.

In the description set forth below, a solar energy collection system 10 is described in the context of being formed by a plurality of solar collection modules, supported so as to be pivotally adjustable for sun-tracking purposes. Each of the modules can include a support member supporting a plurality of solar collection devices as well as wiring for connecting the various solar collection devices to each other and to other modules. The system 10 can also include devices for reducing labor, hardware, or other costs associated with installing such a system. For example, the collection system 10 or the modules included in such a system, can be pivoted by a sun-tracking drive that includes one or more features or has been prepared for operation using one or more of the various steps described below designed to reduce the cost of installation of a photovoltaic electricity farm.

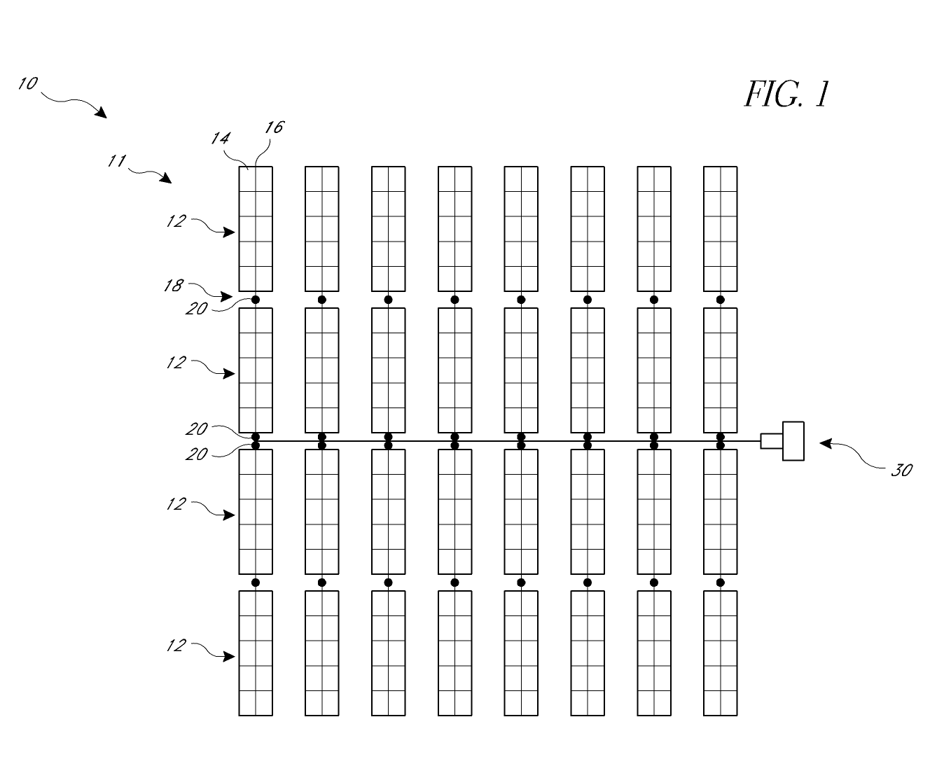

FIG. 1 illustrates the solar collection system 10, which can be considered an electricity farm. The solar collection system 10 includes a solar collector array 11 which includes a plurality of solar collection modules 12. Each of the solar collection modules 12 can include a plurality of solar collecting devices 14 supported by a drive shaft or torque tube 16. Each of the torque tubes 16 are supported above the ground by a support assembly 18. Each of the support assemblies 18 can include a pile and a bearing assembly 20.

With continued reference to FIG. 1, the system 10 can also include a tracking drive 30 connected to the torque tube 16 and configured to pivot the torque tube 16 so as to cause the collector devices 14 to track the movement of the sun. In the illustrated embodiment, the torque tubes 16 are arranged generally horizontally and the modules 12 are connected to each other, as more fully described in U.S. patent application Ser. No. 13/176,276, filed Jul. 5, 2011, the entire contents of which is hereby expressly incorporated by reference. However, inventions disclosed herein can be used in the context of other types of arrangements. For example, the system 10 can include a plurality of modules 12 that are arranged such that the torque tube 16 is inclined relative to horizontal, wherein the torque tubes 16 are not connected in an end to end fashion, such as the arrangement illustrated and disclosed in U.S. Patent Publication No. 2008/0245360. The entire contents of the 2008/0245360 patent publication is hereby expressly incorporated by reference including the illustrations and the descriptions of the bearings 40 and 72. Further, the inventions disclosed herein can be used in conjunction with the systems that provide for controlled tilting about two axes, although not illustrated herein.

Additionally, the solar collection devices 14 can be in the form of photovoltaic panels, thermal solar collection devices, concentrated photovoltaic devices, or concentrated thermal solar collection devices. In the illustrated embodiment, the solar collection devices 14 are in the form of non-concentrated photovoltaic modules.

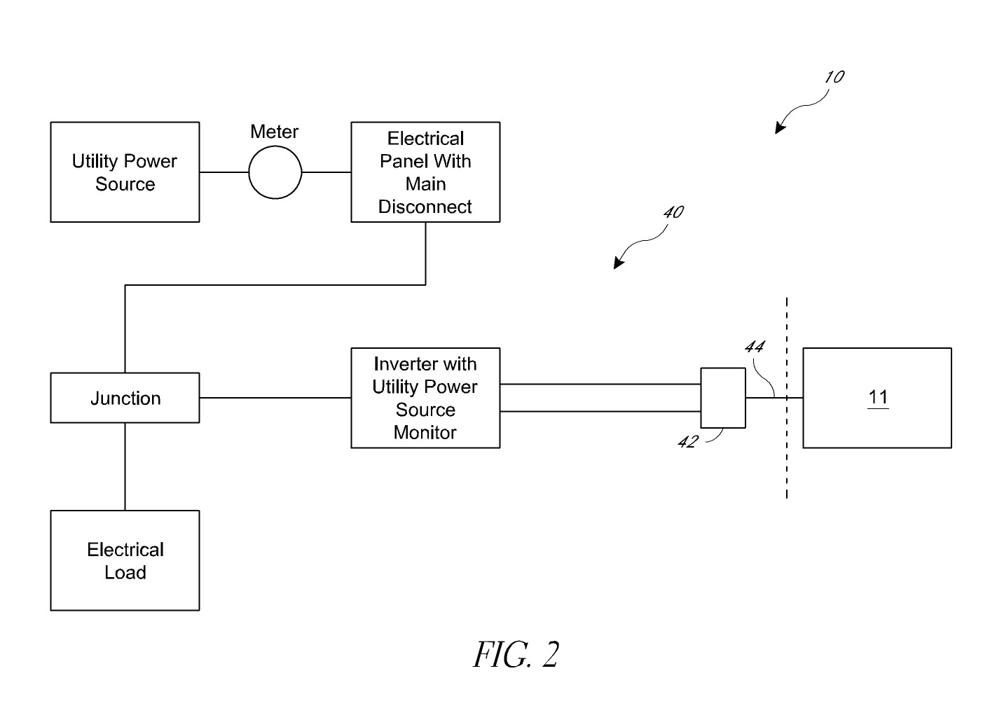

With reference to FIG. 2, solar collection system 10 can further include an electrical system 40 connected to the array 11. For example, the electrical system 40 can include the array 11 as a power source connected to a remote connection device 42 with power lines 44. The electrical system 40 can also include a utility power source, a meter, an electrical panel with a main disconnect, a junction, electrical loads, and/or an inverter with the utility power source monitor. The electrical system 40 can be configured and can operate in accordance with the descriptions set forth in U.S. Patent Publication No. 2010/0071744, the entire contents of which is hereby expressly incorporated by reference.

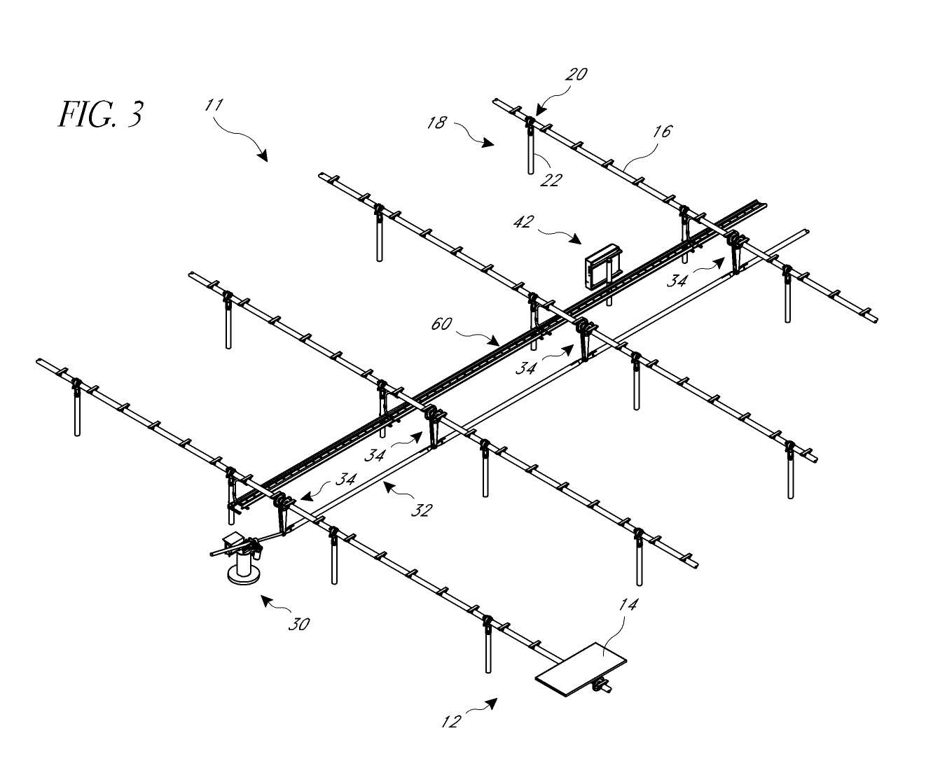

FIG. 3 illustrates the array 11 with all but one of the solar collection devices 14 removed. As shown in FIG. 3, each of the support assemblies 18 includes the bearing 20 supported at the upper end of a pile 22. The torque tube 16 can be of any length and can be formed in one or more pieces. The spacing of the piles 22 relative to one another, can be determined based on the desired limits on deflection of the torque tubes 16 between the support structures 18, wind loads, and other factors.

The tilt drive 30 can include a drive strut 32 coupled with the torque tube 16 in a way that pivots the torque tube 16 as the drive strut 32 is moved axially along its length. The drive strut 32 can be connected with the torque tube 16 with torque arm assemblies 34. In the illustrated embodiment, the torque arm assemblies 34 disposed at an end of each of the torque tube 16. Additionally, the array 11 can include an electrical wire tray 60 supported by one or more of the piles 22, or by other means.

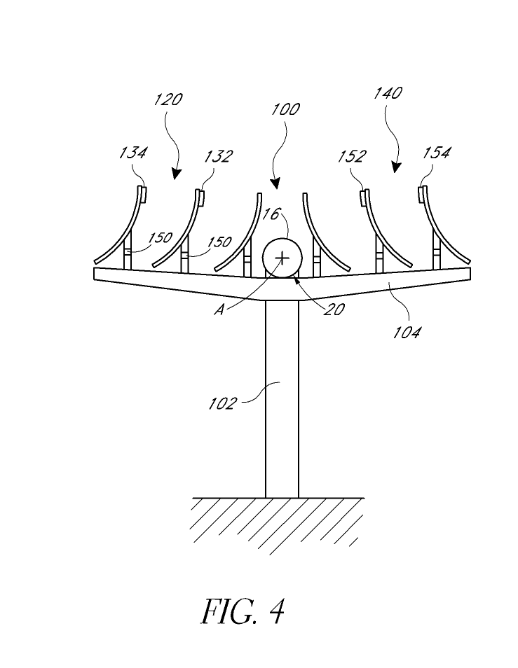

As noted above, and with reference to FIG. 4, the array 11 can be in the form of a plurality of sun tracking, concentrated photovoltaic assemblies. For example, as shown in FIG. 4, a concentrated photovoltaic solar assembly 100 can include a pile 102 which supports one or more cross beams 104 and a torque tube 106. The cross beam 104 in turn supports first and second groups of concentrating elements 120, 140, supported by the cross beam 104.

In the illustrated embodiment, one group of concentrating elements 120 face in one direction and the second group of concentrating elements 140 are positioned so as to face the opposite direction, with the changeover between them occurring at the torque tube 106. The pier 102 can be a single post or one of several supporting the solar concentrator assembly 100.

Connectors 150 support the concentrator elements 120, 140 relative to the cross beam 104. Additionally, photovoltaic collectors 132, 134, 152, 154 can be mounted on the back sides of the concentrator elements 120, 140. In this configuration, each of the concentrator elements 120, 140 are configured to focus a band of concentrated light onto the photovoltaic units 132, 134, 152, 154. A sun-tracking drive system 200 can drive the torque tube 16 to pivot about the pivot axis A. Further detail regarding the optional configuration of a concentrated photovoltaic environment of use is set forth in U.S. patent application Ser. No. 12/977,006 filed Dec. 22, 2010, the entire contents of which is hereby incorporated by reference.

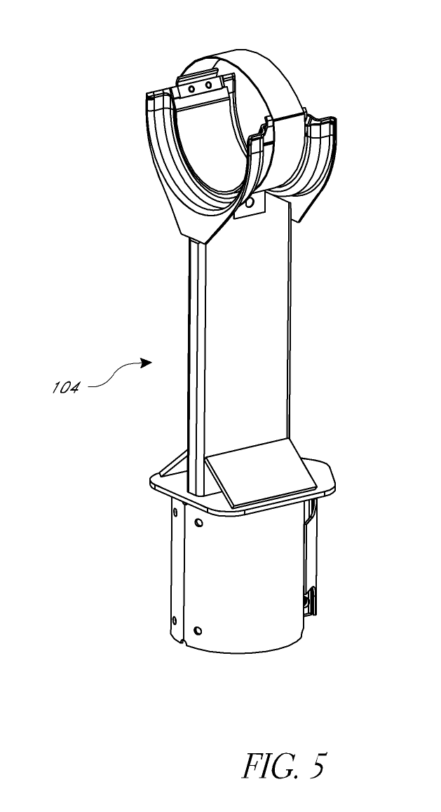

With reference to FIG. 5, the bearings 20 can be supported directly on piers 102 described above with reference to FIGS. 1-4. Optionally, the bearings 20 can be supported upon an optional bearing support 202. As shown in FIG. 5, the bearing support 104 can include a lower end which can be configured to provide a secure connection to a cylindrical pier, such as the piers 102 illustrated in FIGS. 3 and 4. The illustrated bearing support 104 is merely one optional bearing that can be used with the inventions disclosed herein. Further details about the bearing illustrated in FIG. 5 are set forth in U.S. patent application Ser. No. 13/333,964, filed Dec. 21, 2011, the entire contents of which is hereby expressly incorporated by reference. Other bearings can also be used.

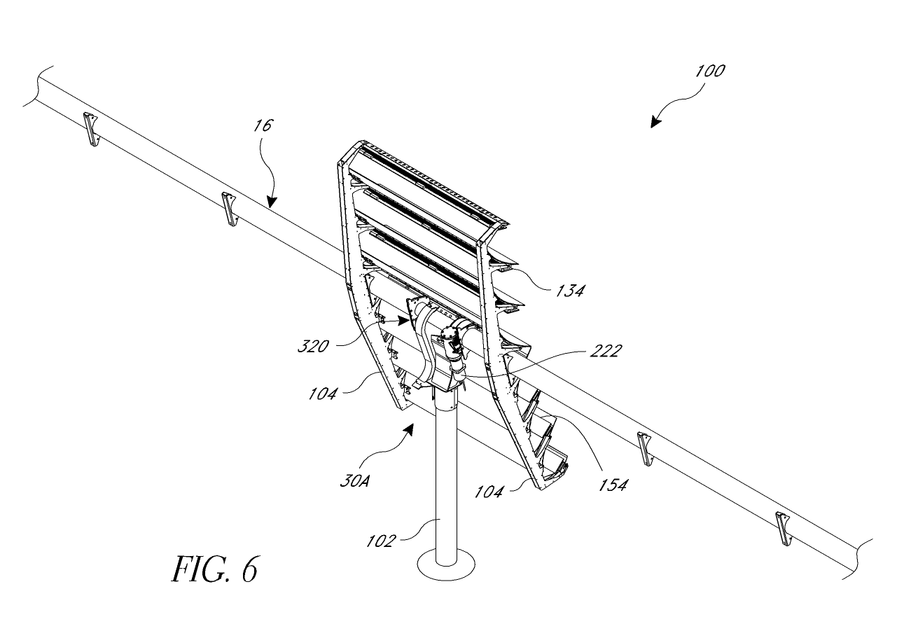

FIG. 6 is a perspective view of an embodiment including the photovoltaic collector assembly illustrated in FIG. 4, with a further embodiment of the sun-tracker drive 30, identified generally by the reference numeral 30A. All of the descriptions noted above with respect to the environment of use and connectivity of the drive 30 also applies to the descriptions set forth below of the sun-tracker drive 30A. The position of the photovoltaic collector assembly 100 illustrated in FIG. 6 is a position that can be used more conveniently for accessing and servicing the sun-tracker drive 30A, but is not a position generally used during generation of electricity.

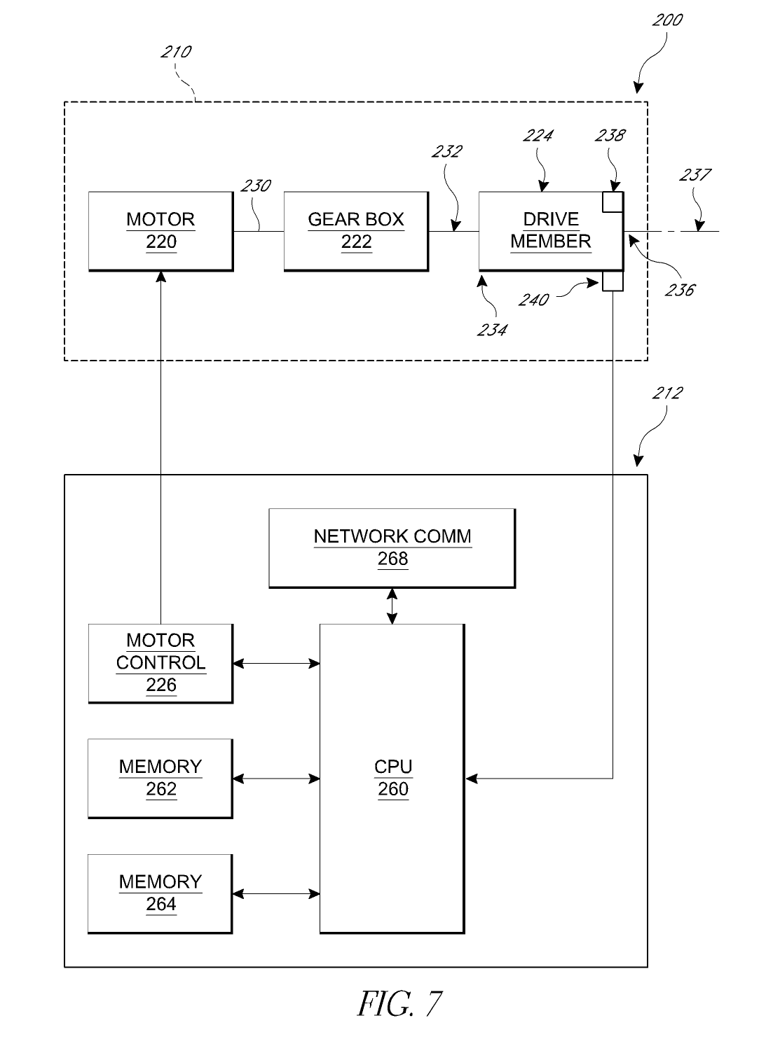

With reference to FIG. 7, the sun-tracking drive 30A can include a drive assembly 210 and a drive controller 212. As shown in FIG. 7, the drive assembly can include a motor 220, a gearbox 222 and a drive member 224.

The motor 220 can be any type of drive motor including, for example, but without limitation, a DC motor, an AC motor, a servo motor, shunt motor, induction motor, stepper motor, etc. Other electric motors can also be used.

An output shaft 230 of the motor is connected to an input of the gearbox 222. The gearbox can be any type of gearbox, and be configured to provide any desired output gear ratio. In the illustrated embodiment, the gear reduction ratio of the gearbox 222 is about 36000:1. In some embodiments, as described below, the gearbox 222 is configured such that its output shaft 232 is at a 90° angle relative to the output shaft 230. This type of motor and gearbox combination is commercially available and typically referred to as a “gearmotor”.

The drive member 224 includes an input end 234 connected to the gearbox 222 and an output end 236 configured for connection to a solar collector. For example, the output end 236 can include a pattern of fastener points, such as holes for threaded fasteners, arranged to provide a secure attachment to a solar collector.

In some embodiments, the drive member 224 can include a reference surface 238. The reference surface 238 can be of any shape or orientation. In some embodiments, the reference surface 238 is configured to provide a conveniently accessible surface that can be used to engage instrumentation for purposes, such as, but without limitation, verify an orientation of the drive member 224 with high precision.

The drive 30A can also include an inclination sensor (“inclinometer”) 240 mounted to any portion of the drive member. The sensitivity of the inclinometer 240 can be affected by the distance at which it is spaced from the tilt axis 237 of the drive member. Thus, the spacing between the inclinometer 240 and the tilt axis 237 can be chosen to provide the desired sensitivity.

The controller 212 can be configured to provide appropriate control over the motor 220 for any purpose. In the illustrated embodiment, the controller 212 is configured to provide feedback control over the motor 220 such that the drive member 224 is driven to and maintained at a desired target orientation, such as a desired inclination. The controller 212 can perform such a feedback control function with any arrangement of sensors. In the illustrated embodiment, the controller 212 uses an output from the inclinometer 240 to control operation of the motor 220.

In some embodiments, the controller 212 can include a central processing unit (CPU) 260, one or more memory devices 262, 264, and a motor controller module 266. Optionally, the controller 212 can include a network communication device 268.

The CPU 260 can be in any known configuration. For example, the CPU 260 can be a purpose-built computer processor, designed to provide the functions described below with regarding to controlling an orientation of the drive member 224. Alternatively, the CPU 260 can be in the form of a general-purpose processor, along with software providing an operating system for performing the functions noted above and described below. In other embodiments, the controller 212 can be in the form of a hardwired control system, in which the CPU 260 represents a logical circuit, configured to provide the functions noted above and described below.

The motor controller 266 can be configured to receive signals from the CPU 260 and to control the delivery of electrical power to the motor 220, to thereby control the direction and speed of the output shaft 230 of the motor 220. Such motor controllers are well known in the art, and thus the internal components of the motor controller 266 are not described further.

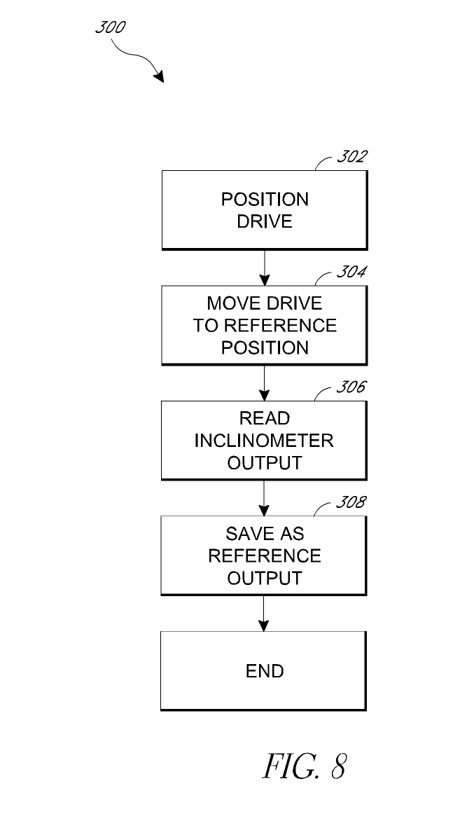

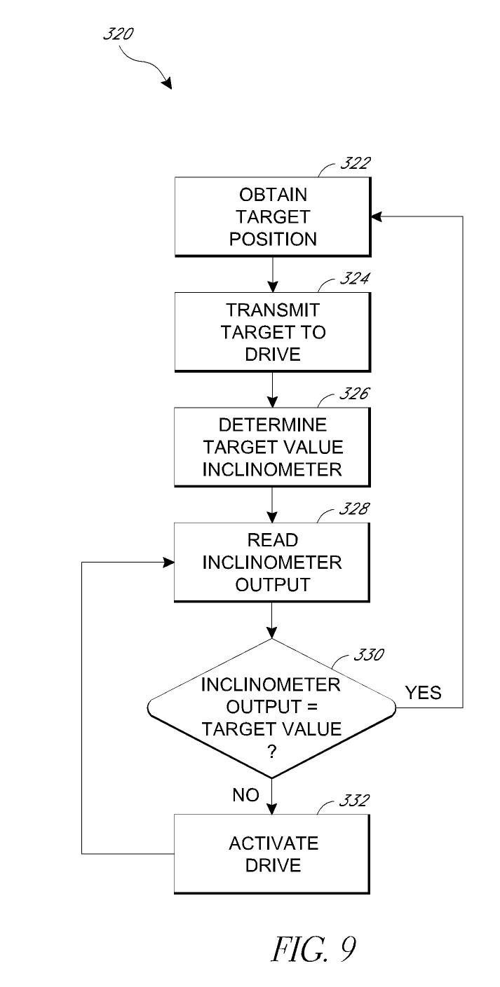

The memory devices 262, 264, as well as other memory devices, can be used to store instructions for performing the functions described below, such as the methods illustrated in FIGS. 8 and 9, as well as other functions and methods. Such stored instructions can be considered as non-transitory, computer readable media. Additionally, one of the memory devices 262, 264 can be used to store reference information, such as an output value from the inclinometer 240, described in greater detail below with regard to FIG. 8.

The network communication device 268 can be used to receive and transmit data and/or signals across a network (not illustrated) to and from the CPU 260. For example, the network communication device 268 can be configured to receive target orientation instructions from a central control system (not illustrated) and transmit those values to the CPU 260 for use in controlling the motor 220, described in greater detail below with reference to FIGS. 8 and 9.

FIG. 8 is a flow chart illustrating an optional method of using the sun-tracker drive 30A. The control routine 300 can be in the form of computer instructions and storable in computer-readable media, such as one of the memory devices 262, 264. Such computer instructions can be written in a way so as to be executable by the CPU 260, using any techniques that are well known in the art. Optionally, as noted above, the CPU 260 can be in the form of a hardwire control system. Thus, in such an environment of use, the method 300 should be considered to describe the functions, steps, etc. described below.

The method 300 can begin with an operation 302 in which the entire sun-tracking drive 30A can be positioned in a protected environment, such as indoors in a manufacturing facility. As such, the calibration procedure noted below can be conducted in a controlled environment. However, other positions can also be used. After the operation 302, the method 300 can move to operation 304.

In operation 304, the drive member 224 is moved to a reference position. For example, the drive member 224 can be rotated until the reference surface 238 of the drive member 224 is in a horizontal position. In some embodiments, the reference surface 238 can be in the form of a flat surface on the drive member that is horizontal, relative to gravity, at a “stowed” position. However, other reference positions can also be used. Optionally, in the operation 304, an additional inclinometer can be used to verify the orientation of the reference surface 238. For example, a high-precision inclinometer, such as a Clinotronic 2000 digital inclinometer sold by Fowler-Wyler, which has a claimed accuracy of less than 5 arc seconds, or other inclinometers, can be used to verify that the reference surface 238 is, in fact, in the reference position. After the operation 304, the method 300 can continue to operation 306.

In the operation 306, the output from the inclinometer 240 can be read. For example, the CPU 260 can sample the output from the inclinometer 240. The inclinometer 240 can be configured to output a signal such as a voltage that is indicative of the angular position of the drive member. Other types of sensors can also be used.

The CPU 260 is configured to receive the output from the inclinometer 240 and to perform mathematical and/or other functions on the output from the inclinometer. After the operation 306, the method 300 can move onto operation 308.

In the operation 308, the output from the inclinometer 240 can be saved as a reference output. For example, the output value from the inclinometer 240 can be saved in memory device 262, 264, or any other memory device. With the reference output saved as such, the controller 212 has a basis for determining the orientation of the drive member 224. For example, if the reference output from the inclinometer 240 has a value of 0.10 volts, the controller 212 can be configured to drive the motor 220 until the output of the inclinometer 240 is 0.10 volts when the controller 212 is instructed to rotated the drive member 224 to the reference position. For other orientations, the reference output can be added or subtracted to target angles transmitted to the controller 212, so as to compensate for the output of the inclinometer 240 when the drive member 224 is at the reference position. After the operation 308, the method 300 can end.

FIG. 9 is a flow chart illustrating an embodiment of a method of using the sun-tracking drive 200. The method 320 can begin in operation 322.

In the operation 322, a target position can be obtained. For example, as noted above, the controller 212 can receive communications from a central controller (not shown) configured to generate target positions for each solar collector device in an electricity farm. Thus, for example, in the operation 322, a target position of −10° can be transmitted to the controller 212. Negative 10°, for example, can be considered a position in which the solar collector assembly 100 is tilted, about the tilt axis 237, by 10° toward the east, relative to the reference horizontal position. After operation 322, the method 320 can move onto operation 324.

In the operation 324, the target position from the operation 322 can be transmitted to the controller 212. For example, as noted above, the controller 212 can include a network communication device 268 configured to receive target positions over a network (not illustrated). Other communication techniques can also be used to transmit a target position to the controller 212. After the operation 324, the method 320 can move on to operation 326.

In the operation 326, the target value of the output from the inclinometer 240 can be determined. For example, with the reference output values saved, as noted above in operation 308 of the method 300, the controller 212 can calculate the required output from the inclinometer 240 to achieve a position corresponding to the target position. For example, if the reference output saved in operation 308 of the method 300 corresponds to +0.5°, then it is known that the inclinometer 240 outputs a value that reads 0.5° west of a horizontal position. Thus, in order to move the drive member 224 to a position corresponding to −10°, the motor 220 must be driven until the output from the inclinometer 240 is or is indicative of a position of −10.5°. Thus, the saved reference output value from operation 308 of method 300 is used to compensate for the calibration of the inclinometer 240, for example, as noted below. After the operation 326, the method 320 can move onto operation 328.

In operation 328, the output value of the inclinometer 240 is read. For example, as noted above, if the drive member is oriented at a position, for example, of +5°, then the output value of the inclinometer 240 would be +5.5°. After the operation 328, the method 320 can move onto decision 330.

In the decision 330, it is determined whether the output from the inclinometer is equal to the target value. For example, the current output from the inclinometer 240 read in operation 328 can be compared to the target value received in operation 324. If the output of the inclinometer read at operation 328 is the same as the target value (or within an acceptable range of the target value such as 0.05 degrees), the method returns to operation 322 and repeats.

If, however, in the decision 330, the output of the inclinometer 240 is not the same as the target value (or within an acceptable range of the target value such as 0.05 degrees), the method 320 can move onto operation 322.

In the operation 322, the motor 220 is activated to rotate. For example, the motor controller 266 can be used to drive the motor 220 in any direction, by any amount. The direction and amount by which the motor 220 is operated can be chosen, by one of ordinary skill in the art, to achieve the desired performance. For example, the motor controller 266 can be configured to operate in pulses whereby the motor 220 is driven only by an amount sufficient to rotate the drive member by 0.01°. Other motor drive parameters can also be used. After the operation 332, the method 320 returns to operation 328 and repeats. For example, as the method 320 returns to operation 328, the output from the inclinometer 240 is read again.

Then, in decision 330, the output of the inclinometer 240 and the target value are again compared. If these values are not equal, the method 320 repeats operation 328, decision 330, and operation 332 until the output of the inclinometer 240 and the target value are equal (or within a desired range relative to each other).

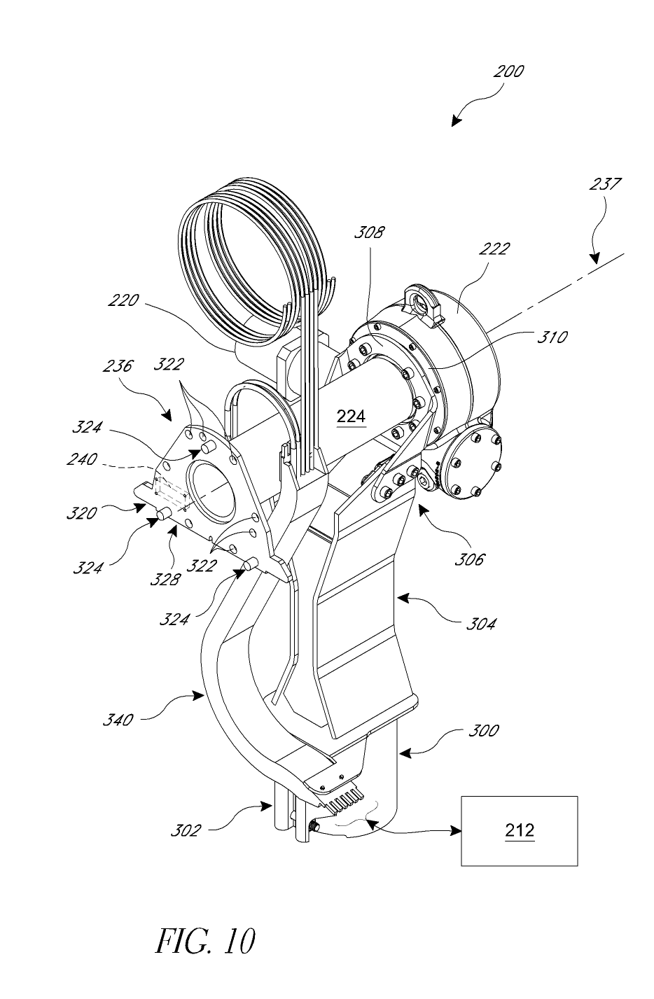

FIG. 10 illustrated an optional configuration of the sun-tracker drive 30A. In the illustrated embodiment, the sun-tracker drive 30A includes a lower portion 300 configured to provide a secure mount to a pile, such as the piles 102, illustrated in FIGS. 1-4. In the illustrated embodiment, the lower portion 300 includes a clamp portion 302 for adjusting the tightness of the connection between the lower portion 300 and the pile 102.

In the illustrated embodiment, the drive 30A includes an hourglass-shaped intermediate portion 304 extending from the lower portion 300 to a support portion 306. The intermediate portion 304, in the illustrated embodiment, is made from a plurality of metal plates, welded together. However, other configurations can also be used.

The upper portion 306 is configured to provide a stable mount for the hardware of the drive 30A. As shown in FIG. 10, a mounting plate 308 connects the upper portion 306 to a mounting face 310 of the gearbox 222. The input end 234 (FIG. 7) of the drive member 224 is connected to an output shaft 232 of the gearbox 222. Optionally, in some embodiments, an additional drive member (not illustrated) can be mounted to the opposite side of the gearbox 222.

The drive member 224 includes a drive plate 320 securely mounted to the output end 236 of the drive member 224. The drive plate 320 includes one or more apertures 322 for receiving fasteners for providing a secure connection to a torque tube, such as the torque tube 16 (FIGS. 4 and 6). Optionally, the plate 320 can also include one or more optional alignment pins 324. Such alignment pins can be shaped and arranged to provide a high-precision connection to the torque tube 16. For example, but without limitation, the pins 324 and corresponding recesses formed on a mating drive plate on a torque tube 106, can be configured to maintain an alignment between the drive member 224 and the torque tube to a tolerance of ½ a degree, 1/10th of a degree, 5/100ths of a degree or less.

Additionally, in some embodiments, the reference surface 238 can be formed on a lower surface of the drive plate 320. As noted above, in some embodiments, the reference surface 238 can be machined flat and oriented such that the reference surface 238 is horizontal relative to gravity when a corresponding collector assembly is in a horizontal orientation. This orientation, as described above, can be considered the reference position used in operation 304 of the method 300 (FIG. 8). This position, as noted above, also corresponds to a reference position of the solar collector assembly 100. Thus, when the reference position 238 is horizontal relative to gravity, then the connected corresponding solar collector assembly 100 is also at the same reference position, e.g., 0° or “stowed.”

Additionally, as illustrated in FIG. 10, the inclinometer 240 can be mounted to the drive plate 320. As noted above, the spacing between the inclinometer 240 and the axis 237 affects the sensitivity of the inclinometer 240. Thus, the spacing between the inclinometer 240 and the axis 237 can be chosen to achieve the desired performance.

The illustrated embodiment of FIG. 10 also includes an optional wire loom 340 which is configured to protect the various wires extending between the controller 212 and the drive hardware 210. Other connections and wire looms can also be used.

With the sun-tracking drive 30A calibrated as such, the drive can be brought to an installation site and the entire procedure for assembling and starting operation of the solar collection system 10 can be greatly reduced. For example, during the construction of a system such as the system 10, the piers 102 are individually secured into the ground, using pile-driving, cement foundations, and the like. However, it is difficult to achieve a very high precision of uniformity in the height and orientation of every pier 102. Thus, some of the piers 102 will not be oriented precisely vertically.

However, using the drive described herein, the drive, such as the drive 30A illustrated in FIG. 10, can be mounted onto a pier at an installation site of the system 10, and the drive 30A can immediately be driven to any desired position. For example, if the drive 30A is activated to turn the reference surface 238 to a horizontal position, the controller 212 can use the output from the inclinometer 240 to properly drive the motor 220. No further calibration would be necessary. Thus, by using such a technique and hardware, it is not necessary to recalibrate each of the drives 200 after they have been installed onto piers 102. This presents a substantial savings in labor and time in constructing a system such as the system 10.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A method of using a sun tracking drive comprising a motor mechanically interfaced with a drive member having a connector configured to engage a frame of a photovoltaic collector assembly such that the motor can drive the frame through a pivoting motion about a tilt axis for tracking movement of a sun, the method comprising:
attaching an inclinometer to the drive member;
rotating the drive member to a reference position;
detecting an output from the inclinometer with the drive member at the reference position;
storing in a memory device an offset value indicative of the output from the inclinometer when the drive member is in the reference position.

2. The method according to claim 1, wherein rotating the drive member comprises rotating the drive member until a reference surface of the drive member reaches a predetermined position.

3. The method according to claim 2 additionally comprising aligning the reference surface with a fixed reference member.

4. The method according to claim 2 additionally comprising detecting an inclination of the reference surface with a second inclinometer.

5. The method according to claim 1 additionally comprising connecting a controller to the motor and connecting the inclinometer to the controller.

6. The method according to claim 5, wherein storing in a memory device comprises storing the offset value in the memory device which is housed in the controller.

7. The method according to claim 1, wherein detecting an output comprises detecting an output of the inclinometer without the drive member being connected to the frame of the concentrated photovoltaic collector assembly.

8. The method according to claim 1 additionally comprising mounting the motor to a support pier, connecting the drive member to the frame of the photovoltaic collector assembly, operating the motor so as to rotate the drive member to the reference position, and determining an inclination of a reference surface of the frame.

9. The method according to claim 8, wherein operating the motor comprises providing energy to the motor until the output of the inclinometer indicates that the drive member is at a horizontal position.

10. The method according to claim 9, wherein determining an inclination comprises determining if the inclination of the reference surface of the frame is horizontal and wherein the reference position of the drive member corresponds to a horizontal position of the frame.

11. The method according to claim 1 additionally comprising connecting the drive member to the frame with a connector configured to provide an alignment of the drive member with the frame member to within a ½ of one degree of tolerance, or less.

12. The method according to claim 11, wherein connecting the drive member to the frame comprises using at least one of a slip fit connector and an interference fit connector.

13. The method according to claim 11, wherein connecting the drive member to the frame comprises connecting the drive member to a frame which supports a plurality of curved mirrors, each of the mirrors defining an aperture and being shaped to focus light onto photovoltaic modules, respectively, a width of the photovoltaic modules being smaller than the apertures.

14. The method according to claim 1 additionally comprising attaching a second drive to the support frame, the second drive being configured to pivot the support frame about a second axis.

15. The method according to claim 1 additionally comprising repeating the steps of claim 1 a plurality of times so as to store a plurality of offset values in a plurality of memory devices, connecting the plurality of drives to a central controller, transmitting control signals indicative of a tilt angle to the plurality of drives from the central controller, operating the motors until the inclinations of the drive members are the same as the respective tilt angles transmitted by the central controller with compensation for the offset value stored in the memory devices.

16. A photovoltaic electricity farm, comprising:
a plurality of support frames, each supporting a plurality of photovoltaic modules and a plurality of solar concentrating mirrors configured to focus light onto the photovoltaic modules, each of the support frames being mounted so as to be pivotable about at least a first tilt axis;
a plurality of sun tracking drives, each sun tracking drive being connected to at least one of the plurality of support frames, each of the plurality of sun tracking drives comprising:
a motor mechanically interfaced with a drive member, the drive member including a connector engaged with one of the plurality of support frames, the motor being configured to pivot the support frame about a tilt axis for tracking movement of a sun;
an inclinometer mounted to the drive member;
a controller including a network communication device and a memory device, the controller being connected to the inclinometer so as to receive an output signal from the inclinometer;
wherein a reference value is stored in the memory device that is indicative of an output of the inclinometer when the drive member was positioned in a reference position before being connected to the support frame.

17. The photovoltaic electricity farm according to claim 16, wherein the drive member comprises a reference surface which is horizontal when the drive member is in the reference position.

18. The photovoltaic electricity farm according to claim 16, wherein each of the sun tracking drives includes a controller housing the memory device and a network communication device.

19. The photovoltaic electricity farm according to claim 16, additionally comprising a plurality of second sun tracking drives, configured to pivot the plurality of support frames about a second axis.

20. A method of using a sun tracking drive comprising a motor mechanically interfaced with a drive member having a connector configured to engage a frame of a concentrated photovoltaic collector assembly such that the motor can drive the frame through a pivoting motion about a tilt axis for tracking movement of a sun, the method comprising:
attaching an inclinometer to the drive member; and
calibrating the position of the drive member with the output of the inclinometer before attaching the drive member to the support frame in an outdoor, photovoltaic electricity farm.
